(19) United States
(12) Patent Application Publication
(10) Pub. No.: US 2024/0318294 A1
(43) Pub. Date: Sep. 26, 2024

(54) APPARATUS FOR MANUFACTURING DISPLAY APPARATUS AND METHOD OF MANUFACTURING DISPLAY APPARATUS

(71) Applicant: Samsung Display Co., LTD., Yongin-si (KR)

(72) Inventors: Jeongkuk Kim, Yongin-si (KR); Duckjung Lee, Yongin-si (KR); Wonje Cho, Yongin-si (KR)

(73) Assignee: Samsung Display Co., LTD., Yongin-si (KR)

(21) Appl. No.: 18/410,643

(22) Filed: Jan. 11, 2024

(30) Foreign Application Priority Data
Mar. 24, 2023 (KR) 10-2023-0039056
May 31, 2023 (KR) 10-2023-0070408

(51) Int. Cl. C23C 14/04; H10K 71/16

(52) U.S. Cl. CPC C23C 14/042; H10K 71/166

(57) ABSTRACT

An apparatus for manufacturing a display apparatus includes a mask assembly. The mask assembly includes a first mask layer, a second mask layer disposed on the first mask layer and including a plurality of deposition holes through which the deposition material is passed, and an adhesive member in contact with the first mask layer.

### CROSS-REFERENCE TO RELATED APPLICATION(S)

This application claims priority to and benefits of Korean Patent Application No. 10-2023-0039056, filed on Mar. 24, 2023, and Korean Patent Application No. 10-2023-0070408, filed on May 31, 2023, under 35 U.S.C. § 119 in the Korean Intellectual Property Office, the entire contents of which are incorporated herein by reference.

### BACKGROUND

### 1. Technical Field

One or more embodiments relate to an apparatus and a method, and more particularly, to an apparatus for manufacturing a display apparatus and a method of manufacturing a display apparatus.

### 2. Description of the Related Art

Display apparatuses visually display image data. Display apparatuses may display images by using light-emitting diodes. The usage of display apparatuses has diversified. Accordingly, various attempts have been made to design display apparatuses with improved quality.

### SUMMARY

One or more embodiments provide an apparatus for manufacturing a display apparatus including a mask assembly having magnetism and having a simplified manufacturing process.

However, embodiments of the disclosure are not limited to those set forth herein. The above and other embodiments will become more apparent to one of ordinary skill in the art to which the disclosure pertains by referencing the detailed description of the disclosure given below.

According to one or more embodiments, an apparatus for manufacturing a display apparatus may include a chamber, a mask assembly disposed inside the chamber to face a display substrate, a magnetic force part disposed inside the chamber to apply magnetic force to the mask assembly, and a deposition source part disposed inside the chamber to face the mask assembly and that supplies a deposition material such that the deposition material may pass through the mask assembly and may be deposited on the display substrate, wherein the mask assembly may include a first mask layer, a second mask layer disposed on the first mask layer and including a plurality of deposition holes through which the deposition material is passed, and an adhesive member in contact with the first mask layer, wherein the first mask layer includes a base layer including a first base opening through which the deposition material is passed and a second base opening spaced apart from the first base opening, and a metal layer including a metal opening overlapping the first base opening, at least a portion of the metal layer being filled in the second base opening, and wherein at least a portion of the adhesive member is filled in the second base opening to bond the base layer and the metal layer.

The second mask layer may include an adhesive opening, and the adhesive opening may be connected to the second base opening.

At least a portion of the adhesive member may be filled in the adhesive opening, and the adhesive member may be in contact with each of the base layer, the metal layer, and the second mask layer.

The second base opening may include a (2-1)st base opening portion in which at least a portion of the metal layer is filled, and a (2-2)nd base opening portion in which at least a portion of the adhesive member is filled and through which the (2-1)st base opening portion is connected to the adhesive opening.

A width of the (2-2)nd base opening portion may be less than a width of the (2-1)st base opening portion.

The adhesive member may not protrude from the second mask layer.

Each of a lateral surface and an upper surface of the metal layer may be in contact with the base layer.

A lower surface of the metal layer may be exposed from the base layer.

The first base opening and the plurality of deposition holes may overlap each other.

Each of the first base opening and the metal opening may be provided in plurality.

According to one or more embodiments, a method of manufacturing a display apparatus may include disposing a display substrate inside a chamber, disposing a mask assembly inside the chamber, applying, by a magnetic force part, magnetic force to the mask assembly, and supplying, by a deposition source part, a deposition material toward the mask assembly, wherein the disposing of the mask assembly may include disposing a second mask layer on a base layer including a first base opening, the second mask layer including a plurality of deposition holes, forming a second base opening in the base layer, the second base opening being spaced apart from the first base opening, forming an adhesive opening in the second mask layer, the adhesive opening being connected to the second base opening, disposing a metal layer in the second base opening, and disposing an adhesive member in the second base opening through the adhesive opening.

The forming of the second base opening may include forming a (2-1)st base opening portion in a lower portion of the base layer, and forming a (2-2)nd base opening portion in an upper portion of the base layer, and the (2-1)st base opening portion may be connected to the adhesive opening through the (2-2)nd base opening portion.

A width of the (2-2)nd base opening portion may be less than a width of the (2-1)st base opening portion.

The disposing of the metal layer may include disposing the metal layer in the (2-1)st base opening portion.

The disposing of the adhesive member may include disposing the adhesive member in the (2-2)nd base opening portion.

The adhesive member may be in contact with each of the base layer, the metal layer, and the second mask layer.

The adhesive member may not protrude from the second mask layer.

Each of a lateral surface and an upper surface of the metal layer may be in contact with the base layer.

A lower surface of the metal layer may be exposed from the base layer.

The first base opening and the plurality of deposition holes may overlap each other.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display apparatus according to an embodiment;

FIG. 2 is a schematic cross-sectional view of a mask assembly according to an embodiment.

FIG. 3 is a schematic plan view of a portion of a mask assembly according to an embodiment;

FIGS. 4, 5, 6, and 7 are schematic cross-sectional views of a mask assembly, for explaining a method of manufacturing a display apparatus according to an embodiment;

FIG. 8 is a schematic perspective view of a display apparatus according to an embodiment;

FIG. 9 is a schematic cross-sectional view of a display apparatus according to an embodiment;

FIG. 10 is a schematic plan view of a display panel according to an embodiment;

FIG. 11 is a schematic diagram of an equivalent circuit of a pixel of a display apparatus according to an embodiment; and

FIG. 12 is a schematic cross-sectional view of a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

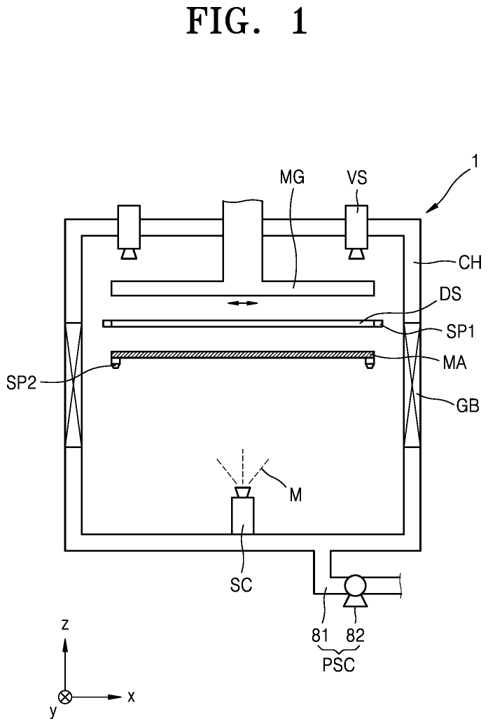

FIG. 1 is a schematic cross-sectional view of an apparatus 1 for manufacturing a display apparatus according to an embodiment.

The apparatus 1 for manufacturing a display apparatus may include a chamber CH, a first supporter SP1, a second supporter SP2, a mask assembly MA, a deposition source part SC, a magnetic force part MG, a vision portion VS, and a pressure adjustor PSC.

A space may be formed inside the chamber CH. A display substrate DS and the mask assembly MA may be received (or filled) in the space. For example, a portion of the chamber CH may be formed to be open. A gate valve GB may be installed in the open portion of the chamber CH. For example, the open portion of the chamber CH may be opened or closed according to an operation of the gate valve GB.

For example, the display substrate DS may denote the display substrate DS in which at least one of an organic layer, an inorganic layer, and a metal layer is deposited on a substrate 100 described below, in case that the display apparatus is manufactured. In another example, the display substrate DS may be the substrate 100 on which any of the organic layer, the inorganic layer, and the metal layer is not yet deposited.

The first supporter SP1 may support the display substrate DS. For example, the first supporter SP1 may have a plate form and may be fixed inside the chamber CH. In another example, the first supporter SP1 may have a shuttle form in which the display substrate DS is seated and which is linearly movable inside the chamber CH. In another example, the first supporter SP1 may include an electrostatic chuck or an adhesive chuck disposed in the chamber CH to be fixed or movable inside the chamber CH.

The second supporter SP2 may support the mask assembly MA. For example, the second supporter SP2 may be disposed inside the chamber CH. The second supporter SP2 may fine-adjust the position of the mask assembly MA. For example, the second supporter SP2 may include a driver, an alignment unit, or the like separately to move the mask assembly MA in various directions.

In another example, the second supporter SP2 may have a shuttle form. For example, the mask assembly MA may be seated on the second supporter SP2. The second supporter SP2 may transfer the mask assembly MA. As an example, the second supporter SP2 may move to the outside of the chamber CH, and after the mask assembly MA is seated on the second supporter SP2, the second supporter SP2 may enter the chamber CH from the outside of the chamber CH.

For example, the first supporter SP1 may be integrally formed with the second supporter SP2. For example, the first supporter SP1 and the second supporter SP2 may include a movable shuttle. For example, the first supporter SP1 and the second supporter SP2 may include a structure that fixes the mask assembly MA to the display substrate DS with the display substrate DS seated on the mask assembly MA, and may linearly move the display substrate DS and the mask assembly MS simultaneously.

Hereinafter, for convenience of description, a form in which the first supporter SP1 and the second supporter SP2 are formed to be discriminated from each other and arranged in different positions, and a form in which the first supporter SP1 and the second supporter SP2 are disposed inside the chamber CH, are described in detail.

The mask assembly MA may be disposed to face the display substrate DS inside the chamber CH. A deposition material M may pass through the mask assembly MA and be deposited on the display substrate DS.

The deposition source part SC may be disposed to face the mask assembly MA and may supply the deposition material M such that the deposition material M may pass through the mask assembly MA and may be deposited on the display substrate DS. For example, the deposition source part SC may evaporate or sublimate the deposition material M by applying heat to the deposition material M. The deposition source part SC may be disposed to be fixed inside the chamber CH, or disposed inside the chamber CH to be linearly move in a direction.

The magnetic force part MG may be disposed inside the chamber CH to face the display substrate DS and/or the mask assembly MA. For example, the magnetic force part MG may apply magnetic force to the mask assembly MA and attract the mask assembly MA toward the display substrate DS.

The vision portion VS may be disposed in the chamber CH and may capture (or measure) the positions of the display substrate DS and the mask assembly MA. For example, the vision portion VS may include a camera that captures the display substrate DS and the mask assembly MA. The positions of the display substrate DS and the mask assembly MA may be determined based on the images captured by the vision portion VS, and the transformation of the mask assembly MA may be determined. For example, the first supporter SP1 may fine-adjust the position of the display substrate DS or the second supporter SP2 may fine-adjust the position of the mask assembly MA based on the captured images. Hereinafter, the case where the second supporter SP2 fine-adjusts the position of the mask assembly MA and align the positions of the display substrate DS and the mask assembly MA, is described in detail.

The pressure adjustor PSC may be connected to the chamber CH and may adjust the inner pressure of the chamber CH. As an example, the pressure adjustor PSC may adjust the inner pressure of the chamber CH to be equal or similar to the atmospheric pressure. For example, the pressure adjustor PSC may adjust the inner pressure of the chamber CH to be equal or similar to a vacuum state.

The pressure adjustor PSC may include a connection pipe 81 and a pump 82. For example, the connection pipe 81 may be connected to the chamber CH, and the pump 82 may be installed to the connection pipe 81. For example, external air may be introduced (or transferred) through the connection pipe 81 or a gas inside the chamber CH may be guided to the outside through the connection pipe 81 according to an operation of the pump 82.

A method of manufacturing the display apparatus by using the apparatus 1 for manufacturing a display apparatus, is described. For example, the display substrate DS may be prepared or provided.

The pressure adjustor PSC may maintain the inside of the chamber CH at a state equal or similar to the atmospheric pressure. The gate valve GB may operate to open the open portion of the chamber CH.

For example, the display substrate DS may be loaded into the inside of the chamber CH from the outside. For example, the display substrate DS may be loaded into the chamber CH in various methods. As an example, the display substrate DS may be loaded into the inside of the chamber CH from the outside of the chamber CH by a robot arm arranged outside the chamber CH. In another example, in the case where the first supporter SP1 is formed in a shuttle form, the first supporter SP1 may be carried from the inside of the chamber CH to the outside of the chamber CH, and the display substrate DS may be seated on the first supporter SP1 by a separate robot arm arranged outside the chamber CH, and the first supporter SP1 may be loaded into the inside of the chamber CH from the outside of the chamber CH.

The mask assembly MA may be arranged inside the chamber CH as described above. In another example, in the same or similar manner to the display substrate DS, the mask assembly MA may be loaded into the inside of the chamber CH from the outside of the chamber CH.

In case that the display substrate DS is loaded into the inside of the chamber CH, the display substrate DS may be seated on the first supporter SP1. For example, the vision portion VS may capture the positions of the display substrate DS and the mask assembly MA. The positions of the display substrate DS and the mask assembly MA may be determined based on images captured by the vision portion VS. For example, the apparatus 1 for manufacturing a display apparatus may include a separate controller to determine the positions of the display substrate DS and the mask assembly MA.

In case that the determination of the positions of the display substrate DS and the mask assembly MA is completed, the second supporter SP2 may fine-adjust the position of the mask assembly MA.

For example, the deposition source part SC may operate to supply the deposition material M toward the mask assembly MA, and the deposition material M passing through the mask assembly MA may be deposited on the display substrate DS. For example, the deposition source part SC may move in parallel to the display substrate DS and the mask assembly MA, or the display substrate DS and the mask assembly MA may move in parallel to the deposition source part SC. For example, the deposition source part SC may move relative to the display substrate DS and the mask assembly MA. For example, the pump 82 may maintain the pressure of the chamber CH at a state equal or similar to vacuum by sucking in the gas inside the chamber CH and discharging the gas to the outside.

As described above, the deposition material M supplied from the deposition source part SC may pass through the mask assembly MA, may be deposited on the display substrate DS, and thus, may form at least one of a plurality of layers, for example, an organic layer, an inorganic layer, and a metal layer stacked in the display apparatus described below.

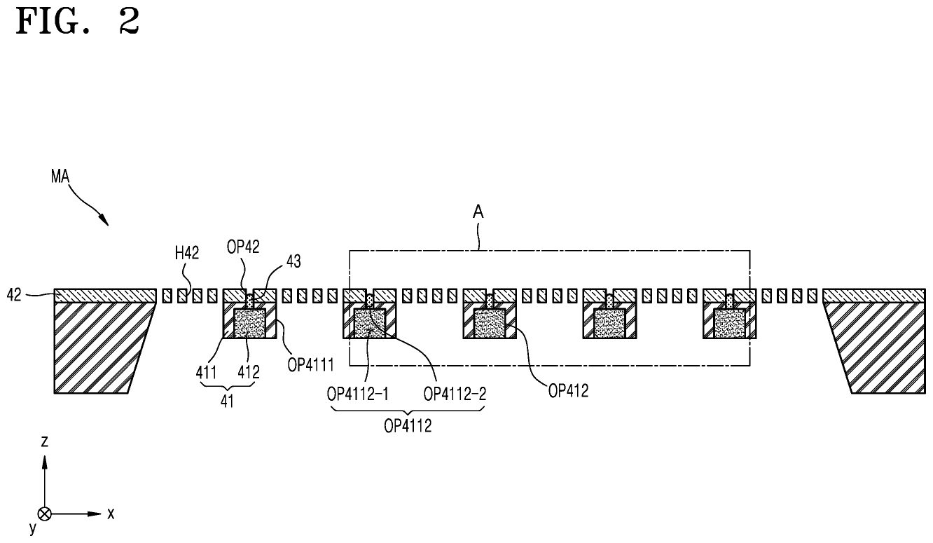

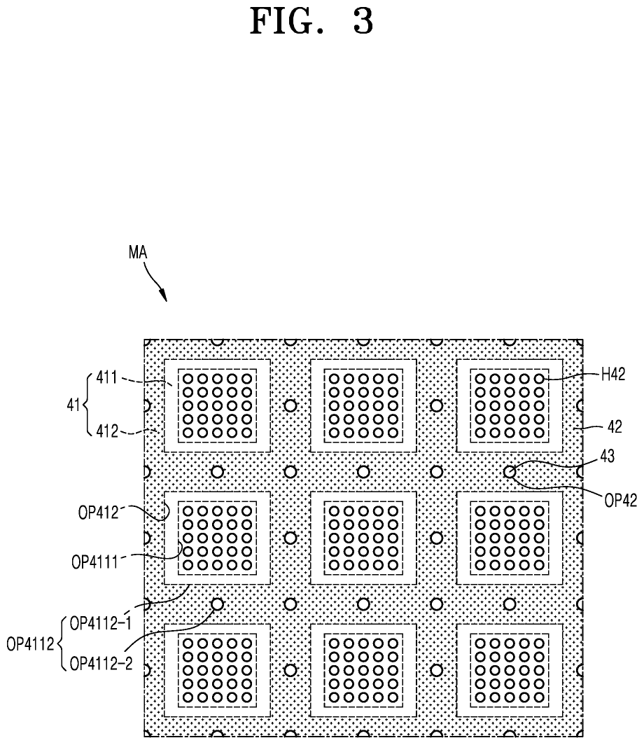

FIG. 2 is a schematic cross-sectional view of the mask assembly MA according to an embodiment, and FIG. 3 is a schematic plan view of a portion of the mask assembly MA according to an embodiment. FIG. 3 is a view of a region A of FIG. 2 viewed from above.

Referring to FIGS. 2 and 3, the mask assembly MA may include a first mask layer 41, a second mask layer 42, and an adhesive member 43.

The first mask layer 41 may include a base layer 411 and a metal layer 412.

The base layer 411 may include a first base opening OP4111 that passes the deposition material M (see FIG. 1). An inner circumferential surface may be formed in the base layer 411 by the first base opening OP4111. The first base opening OP4111 may be disposed in the center portion of the base layer 411. The center portion of the second mask layer 42 may be exposed from the base layer 411 through the first base opening OP4111.

The first base opening OP4111 may be provided in plurality. As an example, as shown in FIG. 3, the plurality of first base openings OP4111 may be arranged in a first direction (e.g., a y-axis direction) and a second direction (e.g., an x-axis direction). Although it is shown in FIG. 3 that the shape of the first base opening OP4111 is quadrangular in a plan view, this is an example, and the shape of the first base opening OP4111 is not limited thereto.

A second base opening OP4112 may be disposed in the base layer 411. For example, the second base opening OP4112 may be spaced apart from the first base opening OP4111. The second base opening OP4112 may include a (2-1)st base opening portion OP4112-1 and a (2-2)nd base opening portion OP4112-2.

As shown in FIG. 3, in a plan view, the (2-1)st base opening portion OP4112-1 may have a lattice shape. The (2-1)st base opening portion OP4112-1 may surround the first base opening OP4111. As shown in FIG. 2, the (2-1)st base opening portion OP4112-1 may collapse in a third direction (e.g., a z-axis direction) from the lower surface of the base layer 411. The (2-1)st base opening portion OP4112-1 may be disposed in the lower portion of base layer 411.

As shown in FIG. 3, in a plan view, the (2-2)nd base opening portion OP4112-2 may overlap the (2-1)st base opening portion OP4112-1. The (2-1)st base opening portion OP4112-1 may be provided in plurality and arranged in the first direction (e.g., the y-axis direction) and the second direction (e.g., the x-axis direction). Although it is shown in FIG. 3 that the shape of the (2-2)nd base opening portion OP4112-2 is circular in a plan view, this is an example, and the shape of the (2-2)nd base opening portion OP4112-2 is not limited thereto.

As shown in FIG. 2, the (2-2)nd base opening portion OP4112-2 may communicate with (or be connected to) the (2-1)st base opening portion OP4112-1. The (2-2)nd base opening portion OP4112-2 may pass through the base layer 411 in the third direction (e.g., the z-axis direction) from the upper surface (or upper portion) of the (2-1)st base opening portion OP4112-1. The (2-2)nd base opening portion OP4112-2 may be disposed on the (2-1)st base opening portion OP4112-1. In a cross-sectional view, the width (or diameter) of the (2-2)nd base opening portion OP4112-2 may be less than the width (or diameter) of the (2-1)st base opening portion OP4112-1.

The base layer 411 may include a silicon material. As an example, the base layer 411 may include at least one of silicon oxide (SiOₓ), silicon nitride (SiNₓ), and silicon oxynitride (SiOₓN_{y}).

At least a portion of the metal layer 412 may be received (or filled) in the second base opening OP4112. As shown in FIG. 2, at least a portion of the metal layer 412 may be received (or filled) in the (2-1)st base opening portion OP4112-1. Each of the lateral surface and the upper surface of the metal layer 412 may be in contact with the base layer 411. The lower surface of the metal layer 412 may be exposed from the base layer 411.

A metal opening OP412 may be disposed in the metal layer 412. For example, the metal opening OP412 may overlap the first base opening OP4111. The metal opening OP412 may be provided in plurality. As an example, as shown in FIG. 3, the metal opening OP412 may be arranged in the first direction (e.g., the y-axis direction) and the second direction (e.g., the x-axis direction). In a plan view, the metal layer 412 may have a lattice shape. The metal layer 412 may surround the first base opening OP4111. Although it is shown in FIG. 3 that the shape of the metal opening OP412 is quadrangular in a plan view, this is an example, and the shape of the metal opening OP412 is not limited thereto.

The metal layer 412 may have magnetism. As an example, the metal layer 412 may include at least one of aluminum (Al), copper (Cu), titanium (Ti), and molybdenum (Mo).

The second mask layer 42 may be disposed on the first mask layer 41. The second mask layer 42 may be supported by the first mask layer 41. Deposition holes H42 may be disposed in the second mask layer 42 to pass the deposition material M (see FIG. 1). The deposition holes H42 may overlap the first base opening OP4111. Accordingly, the deposition material M (see FIG. 1) may pass through the first base opening OP4111 and the deposition holes H42 and reach the display substrate DS (see FIG. 1). Although it is shown in FIG. 3 that the shape of the deposition holes H42 is circular in a plan view, this is an example, and the shape of the deposition holes H42 is not limited thereto.

An adhesive opening OP42 may be disposed in the second mask layer 42. For example, the adhesive opening OP42 may communicate with (or be connected to) the second base opening OP4112. The adhesive opening OP42 may pass through the second mask layer 42 in the third direction (e.g., the z-axis direction) and overlap the (2-2)nd base opening portion OP4112-2. For example, the (2-2)nd base opening portion OP4112-2 may allow the (2-1)st base opening portion OP4112-1 to communicate with (or be connected to) the adhesive opening OP42. As shown in FIG. 3, in a plan view, the adhesive opening OP42 may be provided in plurality and arranged in the first direction (e.g., the y-axis direction) and the second direction (e.g., the x-axis direction). Although it is shown in FIG. 3 that the shape of the adhesive opening OP42 is circular in a plan view, this is an example, and the shape of the adhesive opening OP42 is not limited thereto.

The second mask layer 42 may include at least one of silicon oxide (SiOₓ), silicon nitride (SiNₓ), and silicon oxynitride (SiOₓN_{y}).

The adhesive member 43 may be in contact with the first mask layer 41. At least a portion of the adhesive member 43 may be received (or filled) in the second base opening OP4112 to bond the base layer 411 to the metal layer 412. At least a portion of the adhesive member 43 may be received (or filled) in the (2-2)nd base opening portion OP4112-2. As an example, at least a portion of the adhesive member 43 may be received (or filled) in the (2-2)nd base opening portion OP4112-2 and the adhesive opening OP42, and the adhesive member 43 may be in contact with each of the base layer 411, the metal layer 412, and the second mask layer 42. The adhesive member 43 may fix the base layer 411 to the metal layer 412 by a welding process. As an example, components of the adhesive member 43 include at least one of aluminum (Al), copper (Cu), and tungsten (W).

The adhesive member 43 may not protrude from the second mask layer 42. Accordingly, during the process of depositing the deposition material M (see FIG. 1) to the display substrate DS (see FIG. 1), the adhesive member 43 may not be in contact with the display substrate DS (see FIG. 1). Accordingly, a phenomenon that the display substrate DS (see FIG. 1) is damaged due to contact between the display substrate DS (see FIG. 1) and the adhesive member 43, or the display substrate DS (see FIG. 1) is not in close contact with the second mask layer 42, may be reduced or minimized.

For example, due to the arrangement of the metal layer 412 having magnetism, the magnetic force part MG (see FIG. 1) may apply magnetic force to the mask assembly MA. For example, attractive force may act (or be formed) between the mask assembly MA and the magnetic force part MG (see FIG. 1). Accordingly, the mask assembly MA and the display substrate DS may come into close contact with each other. Accordingly, an error occurring during the process of depositing the deposition material M to the display substrate DS may be reduced or minimized.

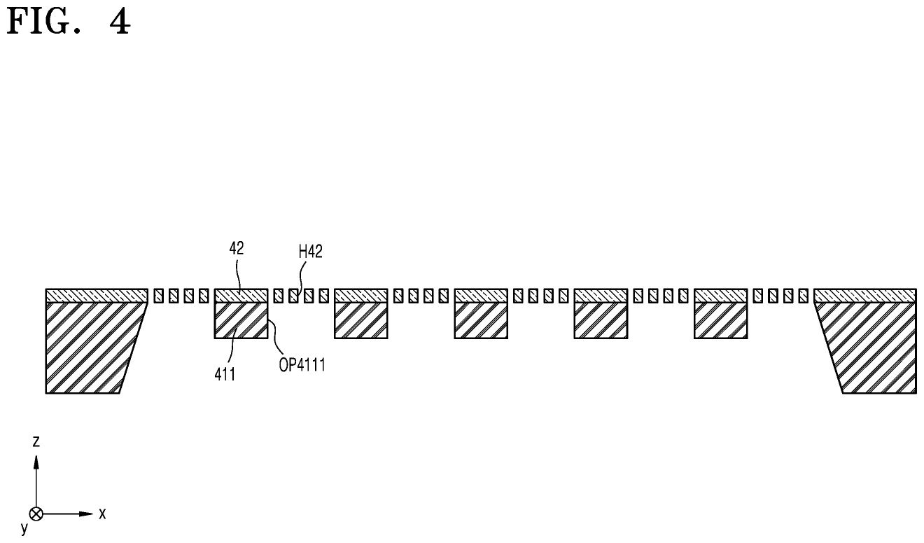

FIGS. 4, 5, 6, and 7 are cross-sectional views of the mask assembly MA, for explaining a method of manufacturing a display apparatus according to an embodiment.

In FIGS. 4, 5, 6, and 7, the same reference numerals as those of FIGS. 1 to 3 denote the same members, and thus, repeated descriptions thereof are omitted.

Referring to FIGS. 4, 5, 6, and 7, the method of manufacturing the display apparatus may include disposing the mask assembly MA inside the chamber CH (see FIG. 1).

The disposing of the mask assembly MA may include disposing the second mask layer 42 including the deposition holes H42 on the base layer 411 including the first base opening OP4111, forming the second base opening OP4112 in the base layer 411. For example, the second base opening OP4112 may be spaced apart from the first base opening 4111, forming the adhesive opening OP42 in the second mask layer 42. For example, the adhesive opening OP42 may communicate with (or be connected to) the second base opening OP4112, disposing the metal layer 412 in the first base opening OP4111, and disposing the adhesive member 43 in the second base opening OP4112 through the adhesive opening OP42.

FIG. 4 shows an operation of disposing the second mask layer 42 on the base layer 411 including the first base opening OP4111. For example, the second mask layer 42 may include the deposition holes H42. The base layer 411 may support the second mask layer 42. The deposition holes H42 and the first base opening OP4111 may overlap each other.

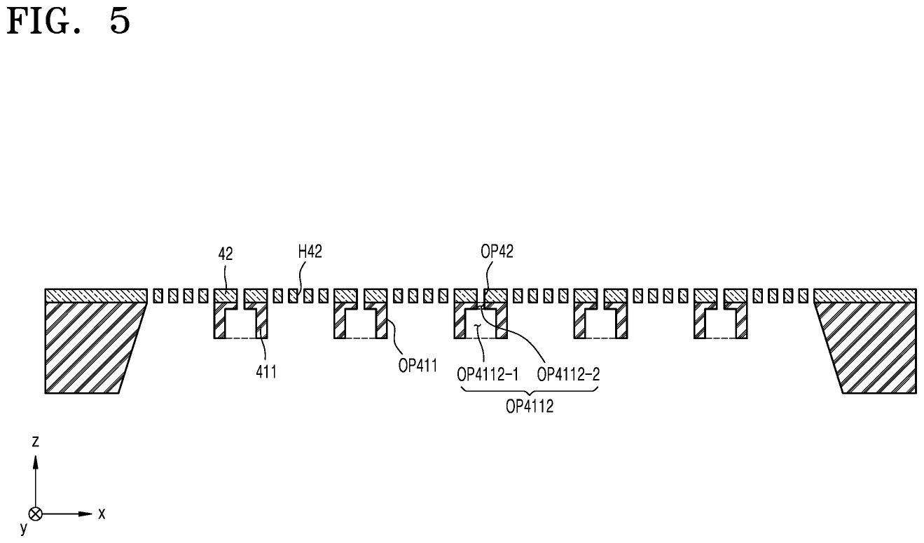

FIG. 5 shows an operation of forming the second base opening OP4112 in the base layer 411. For example, the second base opening OP4112 may be spaced apart from the first base opening OP4111, and an operation of forming the adhesive opening OP42 in the second mask layer 42. For example, the adhesive opening OP42 may communicate with (or be connected to) the second base opening OP4112.

The second base opening OP4112 and the first base opening OP4111 may be formed to be spaced apart from each other. The second base opening OP4112 may include the (2-1)st base opening portion OP4112-1 and the (2-2)nd base opening portion OP4112-2. The forming of the second base opening OP4112 may include forming the (2-1)st base opening portion OP4112-1 in the lower portion of the base layer 411, and forming the (2-2)nd base opening portion OP4112-2 in the upper portion of the base layer 411. For example, the (2-2)nd base opening portion OP4112-2 may communicate with (or be connected to) the (2-1)st base opening portion OP4112-1 and the adhesive opening OP42.

First, the (2-1)st base opening portion OP4112-1 may be formed by etching the base layer 411 from the lower surface of the base layer 411 in the third direction (e.g., the z-axis direction), and the (2-2)nd base opening portion OP4112-2 may be formed by etching the base layer 411 from the upper surface (or upper portion) of the (2-1)st base opening portion OP4112-1 in the third direction (e.g., the z-axis direction).

The adhesive opening OP42 may be formed to be spaced apart from the deposition holes H42. The adhesive opening OP42 may be formed by etching the second mask layer 42 from the upper surface of the second mask layer 42 in the third direction (e.g., the z-axis direction).

As an example, the second base opening OP4112 and the adhesive opening OP42 may be formed by an etching process by using a laser beam. However, this is an example and the second base opening OP4112 and the adhesive opening OP42 may be formed by a photolithography process.

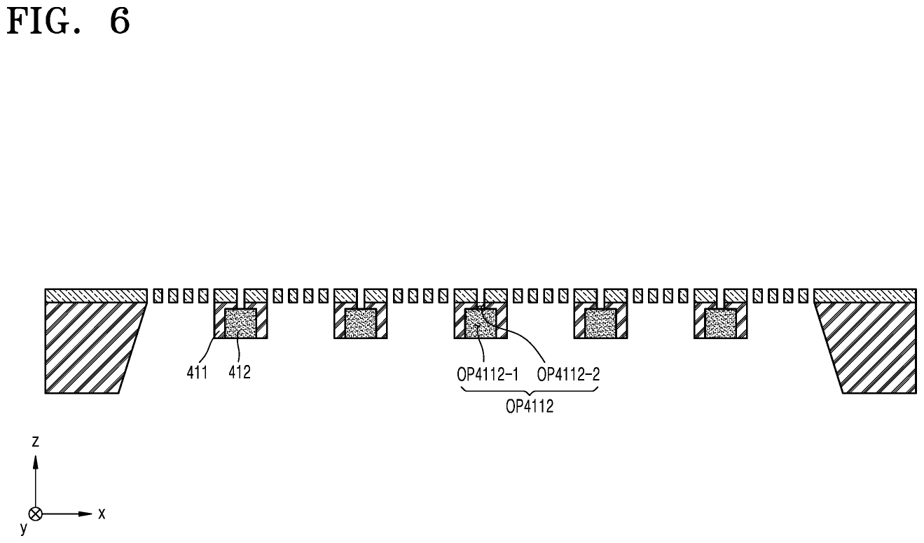

FIG. 6 shows an operation of disposing the metal layer 412 in the first base opening OP4111 of the base layer 411. The disposing of the metal layer 412 may include disposing the metal layer 412 in the (2-1)st base opening portion OP4112-1. With the metal layer 412 disposed, the (2-2)nd base opening portion OP4112-2 may be empty.

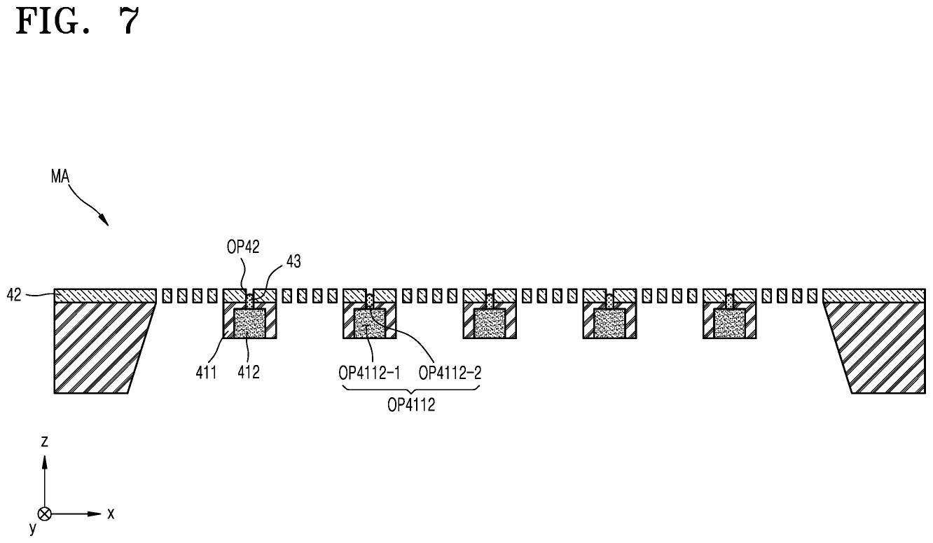

FIG. 7 shows an operation of disposing the adhesive member 43 in the second base opening OP4112 through the adhesive opening OP42. The disposing of the adhesive member 43 may include disposing the adhesive member 43 in the (2-2)nd base opening portion OP4112-2.

At least a portion of the adhesive member 43 may be received (or filled) in the (2-2)nd base opening portion OP4112-2 and be in contact with the metal layer 412 and the base layer 411 received (or filled) in the (2-1)st base opening portion OP4112-1. Accordingly, the adhesive member 43 may fix the metal layer 412 and the base layer 411. At least a portion of the adhesive member 43 may be received (or filled) in the adhesive opening OP42 and be in contact with the second mask layer 42. Accordingly, the adhesive member 43 may fix the metal layer 412, the base layer 411, and the second mask layer 42. As an example, the adhesive member 43 may include a welding material and may be disposed in the second base opening OP4112 by a welding process.

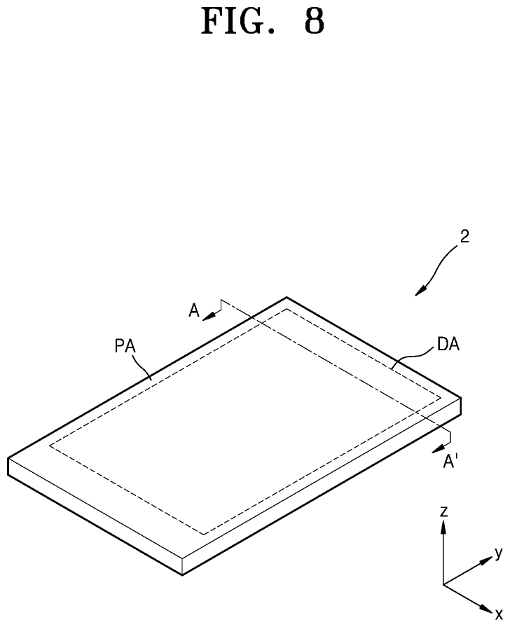

FIG. 8 is a schematic perspective view of a display apparatus 2 according to an embodiment.

Referring to FIG. 8, the display apparatus 2 may include a display area DA and a peripheral area PA surrounding the display area DA. The display apparatus 2 may display images by using light emitted from pixels arranged in the display area DA.

The peripheral area PA may surround (e.g., entirely surround) the display area DA. The peripheral area PA may be a kind of non-display area in which pixels are not arranged and a driver or wirings, which provide electrical signals or power to the pixels, are arranged.

As shown in FIG. 8, although the display apparatus 2 may have a rectangular shape in which a horizontal length is greater than a vertical length, the embodiment is not limited thereto. The display apparatus 2 may have various shapes such as polygons, circles, ellipses, or the like.

Hereinafter, although an organic light-emitting display apparatus is described as an example of the display apparatus 2 according to an embodiment, the display apparatus is not limited thereto. In another example, a display apparatus of another type such as a quantum-dot light-emitting display may be used.

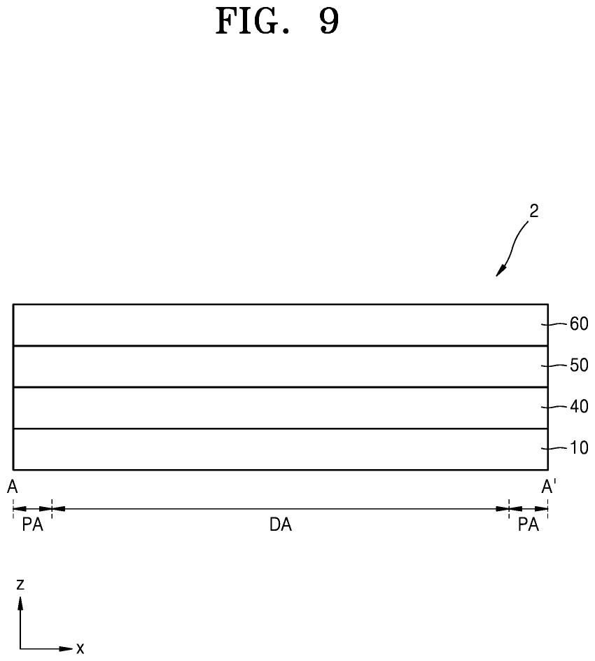

FIG. 9 is a schematic cross-sectional view of a display apparatus according to an embodiment. FIG. 9 may a schematic cross-sectional view taken along line A-A′ of FIG. 8.

Referring to FIG. 9, the display apparatus 2 may include a display panel 10, an input sensing layer 40 disposed on the display panel 10, and an optical functional layer 50. These elements may be covered by a window 60. The display apparatus 2 may be various kinds of electronic apparatuses such as mobile phones, notebook computers, and smartwatches.

The display panel 10 may display images. The display panel 10 may include pixels arranged in the display area DA. The pixels may each include a display element and a pixel circuit connected to the display element. The display element may include an organic light-emitting diode or a quantum-dot organic light-emitting diode, and the like.

The input sensing layer 40 may obtain coordinate information corresponding to an external input, for example, a touch event. The input sensing layer 40 may include a sensing electrode (or a touch electrode) and trace lines connected to the sensing electrode. The input sensing layer 40 may be disposed on the display panel 10. The input sensing layer 40 may sense an external input by using a self-capacitive method and/or a mutual capacitive method.

The input sensing layer 40 may be formed (e.g., directly formed) on the display panel 10, or separately formed and coupled to the display panel 10 by an adhesive layer such as an optical clear adhesive. As an example, the input sensing layer 40 may be successively formed after a process of forming the display panel 10. For example, the input sensing layer 40 may be a portion of the display panel 10, and an adhesive layer may not be disposed between the input sensing layer 40 and the display panel 10. Although it is shown in FIG. 9 that the input sensing layer 40 is disposed between the display panel 10 and the optical functional layer 50, the input sensing layer 40 may be disposed on the optical functional layer 50.

The optical functional layer 50 may include an anti-reflection layer. The anti-reflection layer may reduce reflectivity of light (e.g., external light) incident toward the display panel 10 from outside through the window 60. In an embodiment, the anti-reflection layer may include a black matrix and color filters. The color filters may be arranged according to colors of pieces of light emitted respectively from the pixels of the display panel 10.

In another example, the anti-reflection layer may include a phase retarder and a polarizer. The phase retarder may include a film-type retarder or a liquid crystal-type retarder. The phase retarder may include a λ/2 phase retarder and/or a λ/4 phase retarder. The polarizer may include a film-type polarizer or a liquid crystal-type polarizer. The film-type polarizer may include a stretchable synthetic resin film, and the liquid crystal-type polarizer may include liquid crystals arranged in a certain arrangement. Each of the phase retarder and the polarizer may further include a protective film. The phase retarder and the polarizer itself or the protective film may be defined as a base layer of the anti-reflection layer.

In another example, the anti-reflection layer may include a destructive interference structure. The destructive interference structure may include a first reflection layer and a second reflection layer respectively disposed on different layers. First-reflected light and second-reflected light respectively reflected by the first reflection layer and the second reflection layer may destructively interfere and thus the reflectivity of external light may be reduced or minimized.

In an embodiment, the optical functional layer 50 may be successively formed after a process of forming the display panel 10 and/or the input sensing layer 40. For example, an adhesive layer may not be disposed between the optical function layer 50 and the display panel 10 and/or the input sensing layer 40.

For example, a layer including an optically clear adhesive or an optically clear resin and the like may be disposed between the window 60 and the optical functional layer 50.

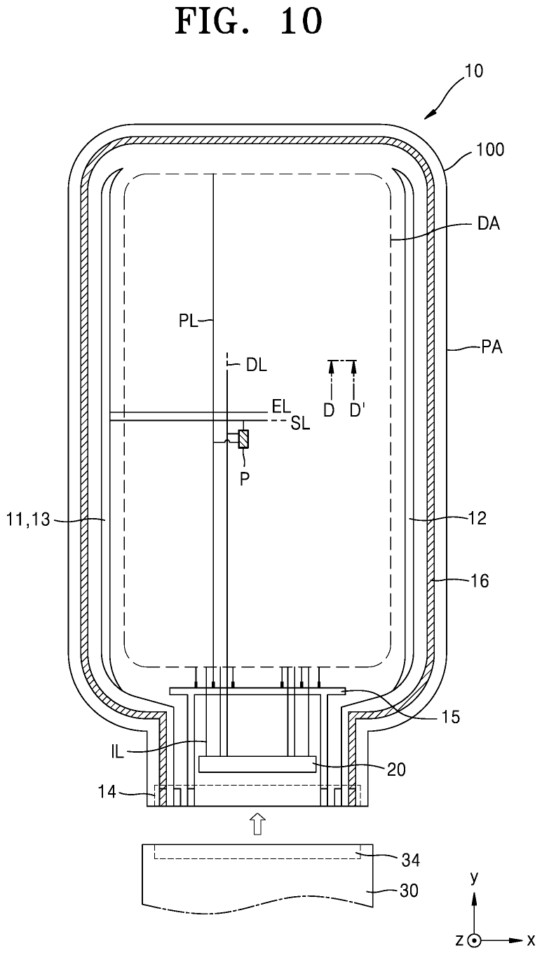

FIG. 10 is a schematic plan view of the display panel 10 according to an embodiment. As described with reference to FIG. 9, the display apparatus according to an embodiment may include the display panel 10. FIG. 10 may be understood as a substrate 100 of the display panel 10.

Referring to FIG. 10, the display panel 10 may include the display area DA and the peripheral area PA outside the display area DA. The display area DA may be a portion that displays images, and pixels P may be arranged in the display area DA. The display area DA may have various shapes, for example, circular shapes, elliptical shapes, polygonal shapes, or shapes of specific figures. It is shown in FIG. 10 that the display area DA has an approximately rectangular shape having round corners.

Each of the pixels P may denote a sub-pixel and include a display element such as an organic light-emitting diode OLED. The pixel P may emit, for example, red light, green light, blue light, or white light.

The peripheral area PA may be arranged outside the display area DA. Outer circuits may be arranged in the peripheral area PA. For example, the outer circuits may drive the pixels P. A first scan driving circuit 11, a second scan driving circuit 12, an emission control driving circuit 13, a terminal 14, a driving power supply line 15, and a common power supply line 16 may be arranged in the peripheral area (or non-display area) PA.

The first scan driving circuit 11 may provide scan signals to the pixel P through a scan line SL. The second scan driving circuit 12 may be arranged in parallel to the first scan driving circuit 11 with the display area DA therebetween. Some of the pixels P arranged in the display area DA may be electrically connected to the first scan driving circuit 11, and the others may be connected to the second scan driving circuit 12. In another example, the second scan driving circuit 12 may be omitted, and all of the pixels P arranged in the display area DA may be electrically connected to the first scan driving circuit 11.

An emission control driving circuit 13 may be arranged on the side of the first scan driving circuit 11 and may provide emission control signals to the pixels P through an emission control line EL. Although it is shown in FIG. 8 that the emission control driving circuit 13 is arranged on a single side of the display area DA, like the first scan driving circuit 11 and the second scan driving circuit 12, the emission control driving circuit 13 may be arranged on two opposite sides of the display area DA.

In an embodiment, the peripheral area PA may include a bent area extending to a side (e.g., a y-axis direction) of the display area DA. The bent area may be bent to the rear surface of the display area DA to reduce the area of the non-display area recognized when viewed from the front surface of the display apparatus.

A driving chip 20 may be arranged in the peripheral area PA. The driving chip 20 may include an integrated circuit that drives the display panel 10. Although the integrated circuit may be a data driving integrated circuit that generates data signals, the embodiment is not limited thereto.

The terminal 14 may be arranged in the peripheral area PA. The terminal 14 may be exposed by not being covered by an insulating layer, and electrically connected to a printed circuit board 30. A terminal 34 of the printed circuit board 30 may be electrically connected to the terminal 14 of the display panel 10.

The printed circuit board 30 may transfer signals of a controller or power to the display panel 10. Control signals generated by the controller may be respectively transferred to the driving circuits through the printed circuit board 30. For example, the controller may transfer a driving voltage ELVDD to the driving power supply line 15 and may transfer a common voltage ELVSS to the common power supply line 16. The driving voltage ELVDD may be transferred to each pixel P through a driving voltage line PL connected to the driving power supply line 15, and the common voltage ELVSS may be transferred to an opposite electrode of the pixel P connected to the common power supply line 16. The driving power supply line 15 may have a shape extending in a direction (e.g., the x-axis direction) below the display area DA. The common power supply line 16 may have a loop shape having an open side and have a shape partially surrounding the display area DA.

The controller may generate data signals, and the generated data signals may be transferred to an input line IL through the driving chip 20 and transferred to the pixel P through a data line DL connected to the input line IL. For reference, a “line” may mean a “wiring”. This is applicable to embodiments below and modifications thereof.

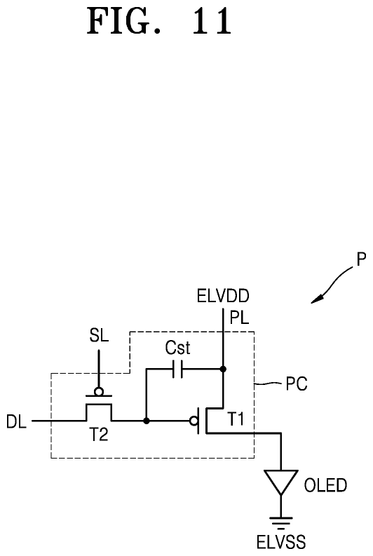

FIG. 11 is a schematic diagram of an equivalent circuit of a pixel of a display apparatus according to an embodiment.

Referring to FIG. 11, the pixel (e.g., a single pixel) P may include a pixel circuit PC and an organic light-emitting diode OLED as a display element connected to the pixel circuit PC. The pixel circuit PC may include a first thin-film transistor T1, a second thin-film transistor T2, and a storage capacitor Cst. Each pixel P may emit, for example, red light, green light, or blue light, or emit red light, green light, blue light, or white light by using the organic light-emitting diode OLED.

The second thin-film transistor T2 may be a switching thin-film transistor, may be connected to a scan line SL and a data line DL, and may transfer a data voltage to the first thin-film transistor T1 based on a switching voltage, the data voltage being input from the data line DL, and the switching voltage being input from the scan line SL. The storage capacitor Cst may be connected to the second thin-film transistor T2 and a driving voltage line PL and may store a voltage corresponding to a difference between a voltage transferred from the second thin-film transistor T2 and the driving voltage ELVDD supplied to the driving voltage line PL.

The first thin-film transistor T1 may be a driving thin-film transistor, may be connected to the driving voltage line PL and the storage capacitor Cst, and may control a driving current according to the voltage stored in the storage capacitor Cst, the driving current flowing from the driving voltage line PL to the organic light-emitting diode OLED. The organic light-emitting diode OLED may emit light having a certain brightness corresponding to the driving current. The opposite electrode (e.g., a cathode) of the organic light-emitting diode OLED may receive the common voltage ELVSS.

Although it is described with reference to FIG. 11 that the pixel circuit PC includes two thin-film transistors and one storage capacitor, the embodiment is not limited thereto. The number of thin-film transistors and the number of storage capacitors may be variously changed according to the design of the pixel circuit PC. As an example, the pixel circuit PC may further include four or more thin-film transistors as well as the two thin-film transistors.

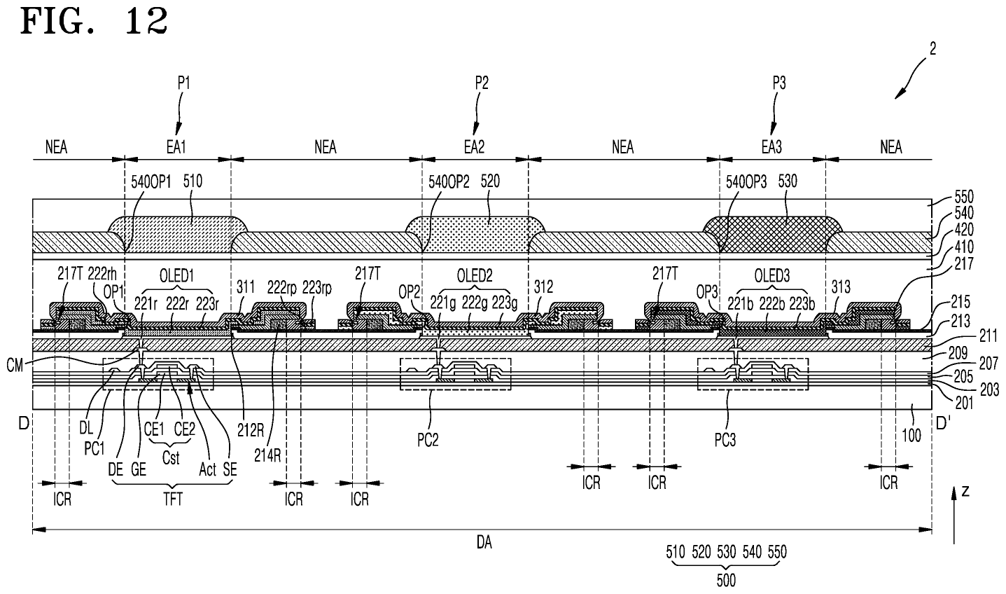

FIG. 12 is a schematic cross-sectional view of the display apparatus according to an embodiment. FIG. 12 is a schematic cross-sectional view taken along line D-D′ of FIG. 10.

Referring to FIG. 12, the display panel 10 may include the substrate 100.

The substrate 100 may include a glass material or polymer resin. In an embodiment, the substrate 100 may have a multi-layered structure in which a base layer and a barrier layer are alternately stacked. The base layer may include polymer resin, and the barrier layer may prevent penetration of an external foreign substance.

The base layer may include a polymer resin such as polyethersulfone (PES), polyarylate (PAR), polyetherimide (PEI), polyethylene naphthalate (PEN), polyethylene terephthalate (PET), polyphenylene sulfide (PPS), polyimide (PI), polycarbonate (PC), cellulose tri acetate (TAC), cellulose acetate propionate (CAP), and the like.

The barrier layer may include an inorganic material such as silicon nitride (SiNₓ) or silicon oxide (SiOₓ).

A first pixel P1, which emits light of a first color, a second pixel P2, which emits light of a second color, and a third pixel P3, which emits light of a third color, may be arranged in the display area DA of the substrate 100. Each of the first, second, and third colors may be one of red, blue, green, and white.

The first pixel P1 may include a first pixel circuit PC1 and a first organic light-emitting diode OLED1 as a display element electrically connected to the first pixel circuit PC1. The second pixel P2 may include a second pixel circuit PC2 and a second organic light-emitting diode OLED2 electrically connected to the second pixel circuit PC2. The third pixel P3 may include a third pixel circuit PC3 and a third organic light-emitting diode OLED3 electrically connected to the third pixel circuit PC3.

A buffer layer 201 may be disposed on the substrate 100. For example, the buffer layer 201 may be formed to prevent impurities from penetrating to a semiconductor layer Act of the thin-film transistor TFT of the first pixel circuit PC1. The buffer layer 201 may include an inorganic insulating material such as silicon nitride (SiNₓ), silicon oxynitride (SiOₓN_{y}), and silicon oxide (SiOₓ), and may include a single layer or a multi-layer including the inorganic insulating materials.

The first pixel circuit PC1, the second pixel circuit PC2, and the third pixel circuit PC3 may be disposed on the buffer layer 201. The first pixel circuit PC1 may include a thin-film transistor TFT and a storage capacitor Cst. The thin-film transistor TFT may include a semiconductor layer Act, a gate electrode GE, a source electrode SE, and a drain electrode DE. The thin-film transistor TFT shown in FIG. 12 may correspond to the first thin-film transistor described with reference to FIG. 11. For example, the data line DL may be electrically connected to a second thin-film transistor included in the first pixel circuit PC1. In the embodiment, though a top-gate type thin-film transistor in which the gate electrode GE is disposed on the semiconductor layer Act with a gate insulating layer 203 therebetween is shown, the thin-film transistor TFT may be a bottom-gate type thin-film transistor in another example. The second pixel circuit PC2 and the third pixel circuit PC3 may have a structure equal or similar to the structure of the first pixel circuit PC1. Hereinafter, each element of the first pixel circuit PC1 is described.

The semiconductor layer Act may include polycrystalline silicon. In another example, the semiconductor layer Act may include amorphous silicon, an oxide semiconductor, or an organic semiconductor. The gate electrode GE may include a low-resistance metal material. The gate electrode GE may include a conductive material including molybdenum (Mo), aluminum (Al), copper (Cu), and titanium (Ti) and have a single-layered structure or a multi-layered structure including the above materials.

The gate insulating layer 203 between the semiconductor layer Act and the gate electrode GE may include silicon oxide (SiOₓ), silicon nitride (SiNₓ), silicon oxynitride (SiOₓN_{y}), aluminum oxide (Al₂O₃), titanium oxide (TiOₓ), tantalum oxide (Ta₂O₅), and hafnium oxide (HfO₂). The gate insulating layer 203 may include a single layer or a multi-layer including the above materials.

The storage capacitor Cst may include a lower electrode CE1 and an upper electrode CE2 overlapping each other with a first interlayer insulating layer 205 between the lower electrode CE1 and the upper electrode CE2. The storage capacitor Cst may overlap the thin-film transistor TFT. It is shown in FIG. 12 that the gate electrode GE of the thin-film transistor TFT functions as the lower electrode CE1 of the storage capacitor Cst. In another example, the storage capacitor Cst may not overlap the thin-film transistor TFT. The storage capacitor Cst may be covered by a second interlayer insulating layer 207. The upper electrode CE2 of the storage capacitor Cst may include a conductive material including molybdenum (Mo), aluminum (Al), copper (Cu), and titanium (Ti) and have a single-layered structure or a multi-layered structure including the above materials.

The first interlayer insulating layer 205 and the second interlayer insulating layer 207 may include an inorganic insulating material such as silicon oxide (SiOₓ), silicon nitride (SiNₓ), silicon oxynitride (SiOₓN_{y}), aluminum oxide (Al₂O₃), titanium oxide (TiOₓ), tantalum oxide (Ta₂O₅), and hafnium oxide (HfO₂). The first interlayer insulating layer 205 and the second interlayer insulating layer 207 may each include a single layer or a multi-layer including the above materials.

The source electrode SE, the drain electrode DE, and the data line DL may be disposed on the same layer, and may include the same material. As an example, the source electrode SE, the drain electrode DE, and the data line DL may be disposed on the second interlayer insulating layer 207. The source electrode SE, the drain electrode DE, and the data line DL may each include a material having high conductivity. The source electrode SE and the drain electrode DE may each include a conductive material including molybdenum (Mo), aluminum (Al), copper (Cu), and titanium (Ti) and include a single layer or a multi-layer including the above materials. In an embodiment, the source electrode SE, the drain electrode DE, and the data line DL may each include a multi-layer of Ti/Al/Ti.

The first pixel circuit PC1, the second pixel circuit PC2, and the third pixel circuit PC3 each including the thin-film transistor TFT and the storage capacitor Cst may be covered by a first organic insulating layer 209. The first organic insulating layer 209 may include an approximately flat upper surface.

The first organic light-emitting diode OLED1 electrically connected to the first pixel circuit PC1, the second organic light-emitting diode OLED2 electrically connected to the second pixel circuit PC2, and the third organic light-emitting diode OLED3 electrically connected to the third pixel circuit PC3 may be disposed on the first organic insulating layer 209.

The first pixel circuit PC1 may be electrically connected to a first pixel electrode 221r of the first organic light-emitting diode OLED1. As an example, as shown in FIG. 12, a contact metal layer CM may be disposed between the thin-film transistor TFT and the first pixel electrode 221r. The contact metal layer CM may be connected to the thin-film transistor TFT through a contact hole passing through the first organic insulating layer 209, and the first pixel electrode 221r may be connected to the contact metal layer CM through a contact hole passing through a second organic insulating layer 211. The contact metal layer CM may include a conductive material including molybdenum (Mo), aluminum (Al), copper (Cu), and titanium (Ti) and have a single-layered structure or a multi-layered structure including the above materials. In an embodiment, the contact metal layer CM may include a multi-layer of Ti/Al/Ti.

The first organic insulating layer 209 and the second organic insulating layer 211 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. In an embodiment, the first organic insulating layer 209 and the second organic insulating layer 211 may each include polyimide.

In another example, one of the first organic insulating layer 209 and the second organic insulating layer 211 may be omitted. For example, the contact metal layer CM may be omitted.

The first organic light-emitting diode OLED1 may include the first pixel electrode 221r, a first emission layer 222r, and a first opposite electrode 223r. The second organic light-emitting diode OLED2 may include a second pixel electrode 221g, a second emission layer 222g, and a second opposite electrode 223g. The third organic light-emitting diode OLED3 may include a third pixel electrode 221b, a third emission layer 222b, and a third opposite electrode 223b. The second organic light-emitting diode OLED2 and the third organic light-emitting diode OLED3 may have a structure equal or similar to the structure of the first organic light-emitting diode OLED1.

The first pixel electrode 221r may be disposed on the second organic insulating layer 211. The first pixel electrode 221r may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another example, the first pixel electrode 221r may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another example, the first pixel electrode 221r may further include a layer, which is disposed on/under the reflective layer and includes ITO, IZO, ZnO, or In₂O₃.

A pixel-defining layer 213 and a bank layer 215 may be disposed on the first pixel electrode 221r. When viewed in a direction (a z-axis direction) approximately perpendicular to the substrate 100, the pixel-defining layer 213 may overlap the edge portions of the first pixel electrode 221r. The pixel-defining layer 213 may include an inorganic insulating material such as silicon nitride (SiNₓ), silicon oxynitride (SiOₓN_{y}), or silicon oxide (SiOₓ).

A first residual sacrificial layer 212R may be disposed between the first pixel electrode 221r and the pixel-defining layer 213. The first residual sacrificial layer 212R may be a portion remaining after a sacrificial layer protecting the upper surface of the first pixel electrode 221r is removed. When viewed in a direction (the z-axis direction) approximately perpendicular to the substrate 100, the first residual sacrificial layer 212R may be arranged in a region in which the pixel-defining layer 213 overlaps the first pixel electrode 221r. As an example, the first residual sacrificial layer 212R may be disposed along the edge portions of the first pixel electrode 221r to expose the center portion of the first pixel electrode 221r.

The first residual sacrificial layer 212R may be continuously formed with the first pixel electrode 221r and may include a material that is selectively etched without a damage to the first pixel electrode 221r. As an example, the first residual sacrificial layer 212R may include indium gallium zinc oxide (IGZO) and/or indium zinc oxide (IZO).

The first residual sacrificial layer 212R and the pixel-defining layer 213 may overlap the edge portions of the first pixel electrode 221r and may prevent arcs (or a short circuit) and the like from occurring between the bank layer 215 and the first opposite electrode 223r by increasing a distance between the bank layer 215 and the first opposite electrode 223r. In an embodiment, the sacrificial layer may be completely removed and the first residual sacrificial layer may not be present. For example, a groove that occurs by removing the sacrificial layer between the first pixel electrode 221r and the pixel-defining layer 213 may be empty, or be filled with the first emission layer 222r described below.

The bank layer 215 may be disposed on the pixel-defining layer 213. The bank layer 215 may include a conductive material. As an example, the bank layer 215 may include a conductive material including molybdenum (Mo), aluminum (Al), copper (Cu), and titanium (Ti) and have a single-layered structure or a multi-layered structure including the above materials. As an example, the bank layer 215 may include a double-layered structure of Al/Ti or a triple-layered structure of Ti/Al/Ti.

The pixel-defining layer 213 and the bank layer 215 may extend from the display area DA to the peripheral area PA (see FIG. 10), and the bank layer 215 may be in contact with (e.g., in direct contact with) the common power supply line 16 (see FIG. 10) arranged in the peripheral area (see FIG. 10) through an opening of the pixel-defining layer 213. Accordingly, the bank layer 215 may function as a kind of connection electrode or auxiliary line that transfers the common voltage ELVSS to the first opposite electrode 223r, the second opposite electrode 223g, and the third opposite electrode 223b described below.

A first conductive layer 217 may be disposed on the bank layer 215. The first conductive layer 217 may include a tip 217T protruding outward from the center portion of the first pixel electrode 221r. When viewed in a direction (the z-axis direction) approximately perpendicular to the upper surface of the substrate 100, the tip 217T of the first conductive layer 217 may have a loop shape surrounding (e.g., completely surrounding) the first pixel electrode 221r.

A first opening OP1 may pass through the pixel-defining layer 213, the bank layer 215, and the first conductive layer 217 to expose the center portion of the upper surface of the first pixel electrode 221r, and the first emission layer 222r described below may overlap and contact the first pixel electrode 221r through the first opening OP1. Accordingly, the first opening OP1 may define a first emission area EA1. The outside of the first emission area EA1 may be defined as a non-emission area NEA. For example, a second opening OP2 may define a second emission area EA2, and a third opening OP3 may define a third emission area EA3.

A portion of the first conductive layer 217 may be spaced apart in a direction (the z-axis direction) perpendicular to the bank layer 215 and the substrate 100 and may form a tip 217T protruding to the outer side from the center portion of the first pixel electrode 221r. Because the tip 217T of the first conductive layer 217 is formed in case that a portion of the sacrificial layer disposed between the first conductive layer 217 and the bank layer 215 is removed, the first conductive layer 217 may have an undercut structure. Accordingly, the tip 217T of the first conductive layer 217 may form an eaves structure whose lower surface is exposed. A protrusion length of the tip 217T of the first conductive layer 217 may be about 0.5 μm or more. In an embodiment, the protrusion length of the tip 217T of the first conductive layer 217 may be about 0.3 μm to about 1 μm or about 0.3 μm to about 0.7 μm.

The first conductive layer 217 may include a conductive material. As an example, the first conductive layer 217 may include a conductive material including molybdenum (Mo), aluminum (Al), copper (Cu), and titanium (Ti) and have a single-layered structure or a multi-layered structure including the above materials. As an example, the first conductive layer 217 may include a double-layered structure of Al/Ti or a triple-layered structure of Ti/Al/Ti.

In an embodiment, a low-reflective layer may be disposed on the first conductive layer 217. The low-reflective layer may be a layer having a surface reflectivity less than a surface reflectivity of the first conductive layer 217. The low-reflective layer may prevent light (e.g., external light) incident toward the display apparatus 2 from being reflected from the surface of the first conductive layer 217 and being recognized by a user of the display apparatus 2.

In an embodiment, the low-reflective layer may include a low-reflective material. The low-reflective material may include a metal oxide having a high light absorption rate, e.g., a high extinction coefficient k. As an example, the low-reflective layer may include at least one of copper oxide (CuO), calcium oxide (CaO), molybdenum oxide (MoOx), and zinc oxide (ZnO). In an embodiment, the low-reflective layer may include a mixture of copper oxide (CuO) and calcium oxide (CaO).

A second residual sacrificial layer 214R may be disposed between the first conductive layer 217 and the first conductive layer 217. The second residual sacrificial layer 214R may be a residual portion of the sacrificial removed to form the tip 217T of the first conductive layer 217. When viewed in a direction (the z-axis direction) approximately perpendicular to the substrate 100, the second residual sacrificial layer 214R may have a loop shape spaced apart from the first pixel electrode 221r by a certain distance and surrounding (e.g., completely surrounding) the first pixel electrode 221r. The first conductive layer 217 may have an undercut structure due to the second residual sacrificial layer 214R.

The second residual sacrificial layer 214R may determine a protrusion length of the tip 217T of the first conductive layer 217. As an example, the second residual sacrificial layer 214R may be positioned inside the end portion of the tip 217T of the first conductive layer 217, and the protrusion length of the tip 217T may be a length from the lateral wall of the second residual sacrificial layer 214R to the end portion of the tip 217T.

The second residual sacrificial layer 214R may include a material that is selectively etched without a damage to the bank layer 215 and the first conductive layer 217. As an example, the second residual sacrificial layer 214R and the first residual sacrificial layer 212R may include the same material. The second residual sacrificial layer 214R may include indium gallium zinc oxide (IGZO) and/or indium zinc oxide (IZO).

The first emission layer 222r may be disposed over the first pixel electrode 221r and the first conductive layer 217. As an example, the first emission layer 222r may be arranged to be in contact with the first pixel electrode 221r through the first opening OP1. The first pixel electrode 221r may include a polymer organic material or a low-molecular weight organic material that emits light having a first color (e.g., red). In another example, the first emission layer 222r may include an inorganic material or quantum dots.

The first emission layer 222r may include a first functional layer and a second functional layer on the upper surface and/or lower surface thereof. The first functional layer may include a hole transport layer (HTL) and/or a hole injection layer (HIL). The second functional layer may include an electron transport layer (ETL) and/or an electron injection layer (EIL).

Although FIG. 12 shows a single stack structure including a single emission layer, the display apparatus 2 may have a tandem structure that is a multi-stack structure including emission layers in an embodiment. In the case where the display apparatus 2 has a tandem structure, a charge generation layer CGL may be disposed between the plurality of stacks.

The first emission layer 222r may be disconnected from a dummy portion 222rp by the tip 217T of the first conductive layer 217. For example, the first emission layer 222r may include the same material and/or the same number of sub-layers (e.g., the first functional layer, the second functional layer and the like) as the dummy portion 222rp.

The first emission layer 222r may have at least one first hole 222rh exposing a portion of the upper surface of the first conductive layer 217.

The second emission layer 222g may include a polymer organic material or a low-molecular weight organic material that emits light of a second color (e.g., green), and the third emission layer 222b may include a polymer organic material or a low-molecular weight organic material that emits light of a third color (e.g., blue).

The first opposite electrode 223r may be disconnected from a dummy portion 223rp by the tips 217T of the first conductive layer 217. The first opposite electrode 223r may include the same material as a material of the dummy portion 223rp.

The first opposite electrode 223r may include a transparent layer (or semi-transparent layer) including silver (Ag), magnesium (Mg), aluminum (Al), platinum (Pt), palladium (Pd), gold (Au), nickel (Ni), neodymium (Nd), iridium (Ir), chrome (Cr), or an alloy thereof. In another example, the first opposite electrode 223r may further include a layer on the transparent layer (or semi-transparent layer), the layer including ITO, IZO, ZnO, or In₂O₃.

A first inorganic encapsulation layer 311 may be disposed on the first opposite electrode 223r. Because the first inorganic encapsulation layer 311 has a relatively excellent step coverage, the first inorganic encapsulation layer 311 may cover at least a portion of the exposed lower surface of the tip 217T of the first conductive layer 217. As an example, the first inorganic encapsulation layer 311 may be continuously formed to cover the upper surface and lateral surfaces of the first opposite electrode 223r, the lateral surfaces of the first emission layer 222r, the lateral surfaces and lower surface of the tip 217T of the first conductive layer 217, the lateral surfaces of the second residual sacrificial layer 214R, and the upper surface of the bank layer 214.

The first inorganic encapsulation layer 311 may include an inorganic insulating material such as silicon nitride (SiNₓ), silicon oxynitride (SiOₓN_{y}), and silicon oxide (SiOₓ). The first inorganic encapsulation layer 311 may be in contact with (e.g., in direct contact with) the metal surface on the lateral surfaces and lower surface of the first conductive layer 217 to form an inorganic contact region ICR. Accordingly, the inorganic contact region ICR may form a closed loop surrounding (e.g., completely surrounding) the first organic light-emitting diode OLED1 to reduce or block a path through which impurities such as moisture and/or air penetrates.

As shown in FIG. 12, a second inorganic encapsulation layer 312 may encapsulate the second organic light-emitting diode OLED2, and a third inorganic encapsulation layer 313 may encapsulate the third organic light-emitting diode OLED3. Because the first inorganic encapsulation layer 311, the second inorganic encapsulation layer 312, and the third inorganic encapsulation layer 313 form the inorganic contact region ICR inside the display area DA, an inorganic contact region of the peripheral area PA (see FIG. 10) required to reducing an exfoliation defect due to the emission layer may be reduced or minimized. For example, because the organic light-emitting diode is encapsulated on a pixel basis, even in the case where a path through which impurities such as moisture and/or air penetrates occurs in the boundary of one pixel or the substrate 100, a defect due to this may be prevented from propagating to the neighboring pixels.

An organic planarization layer 410 may be disposed to cover the first inorganic encapsulation layer 311, the second inorganic encapsulation layer 312, and the third inorganic encapsulation layer 313. The organic planarization layer 410 may cover irregularities due to the pixel-defining layer 213, the bank layer 215, and the first conductive layer 217 and provide a flat base layer to elements disposed on the organic planarization layer 410. The organic planarization layer 410 may include a polymer-based material. The polymer-based material may include an acryl-based resin, an epoxy-based resin, polyimide, and polyethylene.

In an embodiment, a refractive index of the organic planarization layer 410 may be greater than refractive indexes of the first inorganic encapsulation layer 311, the second inorganic encapsulation layer 312, and the third inorganic encapsulation layer 313. As an example, the refractive index of the organic planarization layer 410 may be about 1.6 or more. The refractive index of the organic planarization layer 410 may be about 1.6 to about 1.9. The organic planarization layer 410 may further include dispersion particles for high refractive index. As an example, metal oxide particles such as zinc oxide (ZnOₓ), titanium oxide (TiO₂), zirconium oxide (ZrO₂), or barium titanate (BaTiO₃) may be dispersed in the organic planarization layer 410.

A protective layer 420 may be disposed on the organic planarization layer 410. The protective layer 420 may include an inorganic insulating material such as silicon nitride (SiNₓ), silicon oxynitride (SiOₓN_{y}), and silicon oxide (SiOₓ). In an embodiment, the refractive index of the protective layer 420 may be less than the refractive index of the organic planarization layer 410.

An anti-reflection layer 500 may be disposed on the protective layer 420. For example, the anti-reflection layer 500 may include a first color filter 510, a second color filter 520, a third color filter 530, a light-blocking layer 540, and an overcoat layer 550. The anti-reflection layer 500 may reduce reflectivity of light (e.g., external light) incident toward the display apparatus 2 from the outside.

The light-blocking layer 540 may overlap the bank layer 215 and the first conductive layer 217 to at least partially absorb reflected light due to the bank layer 215 and the first conductive layer 217 in a non-emission area NEA. For example, the non-emission area NEA may be defined as a region not overlapping the first emission area EA1, the second emission area EA2, and the third emission area EA3. The light-blocking layer 540 may include black pigment. The light-blocking layer 540 may be a black matrix. The light-blocking layer 540 may include a first filter opening 540OP1 corresponding to the first emission area EA1, a second filter opening 540OP2 corresponding to the second emission area EA2, and a third filter opening 540OP3 corresponding to the third emission area EA3.

The first color filter 510 may be disposed inside the first filter opening 540OP1 to correspond to the first emission layer 222r. The first color filter 510 may selectively pass light emitted from the first emission layer 222r. As an example, the first color filter 510 shown in FIG. 12 may be a red color filter that passes red light.

For example, the second color filter 520 may be disposed inside the second filter opening 540OP2 to correspond to the second emission layer 222g. The second color filter 520 may selectively pass light emitted from the second emission layer 222g. The third color filter 530 may be disposed inside the third filter opening 540OP3 to correspond to the third emission layer 222b. The third color filter 530 may selectively pass light emitted from the third emission layer 222b. As an example, the second color filter 520 shown in FIG. 12 may be a green color filter that passes green light, and the third color filter 530 may be a blue color filter that passes blue light.

The overcoat layer 550 may be disposed on the first to third color filters 510, 520, and 530. The overcoat layer 550 may be a light-transmissive layer, surrounds irregularities due to the first to third color filters 510, 520, and 530, and the light-blocking layer 540, and provides a flat upper surface. The overcoat layer 550 may include a colorless light-transmissive organic material such as an acryl-based resin.

According to an embodiment, in the apparatus for manufacturing a display apparatus, a manufacturing speed may be improved, a phenomenon that the display substrate is damaged may be reduced, and durability of the mask assembly may be improved.

Effects of the disclosure are not limited to the above mentioned effects and other effects not mentioned may be clearly understood by those of ordinary skill in the art from the following claims.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. An apparatus for manufacturing a display apparatus, the apparatus comprising:
a chamber;
a mask assembly disposed inside the chamber to face a display substrate;
a magnetic force part disposed inside the chamber to apply magnetic force to the mask assembly; and
a deposition source part disposed inside the chamber to face the mask assembly, the deposition source part that supplies a deposition material such that the deposition material passes through the mask assembly and is deposited on the display substrate, wherein
the mask assembly includes:
a first mask layer;
a second mask layer disposed on the first mask layer and including a plurality of deposition holes through which the deposition material is passed; and
an adhesive member in contact with the first mask layer,
the first mask layer includes:
a base layer including:
a first base opening through which the deposition material is passed, and
a second base opening spaced apart from the first base opening; and
a metal layer including a metal opening overlapping the first base opening, at least a portion of the metal layer being filled in the second base opening, and
at least a portion of the adhesive member is filled in the second base opening to bond the base layer and the metal layer.

2. The apparatus of claim 1, wherein
the second mask layer includes an adhesive opening, and
the adhesive opening is connected to the second base opening.

3. The apparatus of claim 2, wherein
at least a portion of the adhesive member is filled in the adhesive opening, and
the adhesive member is in contact with each of the base layer, the metal layer, and the second mask layer.

4. The apparatus of claim 2, wherein the second base opening includes:
a (2-1)st base opening portion in which at least a portion of the metal layer is filled; and
a (2-2)nd base opening portion in which at least a portion of the adhesive member is filled, the (2-2)nd base opening portion through which the (2-1)st base opening portion is connected to the adhesive opening.

5. The apparatus of claim 4, wherein a width of the (2-2)nd base opening portion is less than a width of the (2-1)st base opening portion.

6. The apparatus of claim 2, wherein the adhesive member does not protrude from the second mask layer.

7. The apparatus of claim 1, wherein each of a lateral surface and an upper surface of the metal layer is in contact with the base layer.

8. The apparatus of claim 1, wherein a lower surface of the metal layer is exposed from the base layer.

9. The apparatus of claim 1, wherein the first base opening and the plurality of deposition holes overlap each other.

10. The apparatus of claim 1, wherein each of the first base opening and the metal opening is provided in plurality.

11. A method of manufacturing a display apparatus, the method comprising:
disposing a display substrate inside a chamber;
disposing a mask assembly inside the chamber;
applying, by a magnetic force part, magnetic force to the mask assembly; and
supplying, by a deposition source part, a deposition material toward the mask assembly, wherein
the disposing of the mask assembly includes:
disposing a second mask layer on a base layer including a first base opening, the second mask layer including a plurality of deposition holes;
forming a second base opening in the base layer, the second base opening being spaced apart from the first base opening;
forming an adhesive opening in the second mask layer, the adhesive opening being connected to the second base opening;
disposing a metal layer in the second base opening; and
disposing an adhesive member in the second base opening through the adhesive opening.

12. The method of claim 11, wherein
the forming of the second base opening includes:
forming a (2-1)st base opening portion in a lower portion of the base layer; and
forming a (2-2)nd base opening portion in an upper portion of the base layer, and
the (2-1)st base opening portion is connected to the adhesive opening through the (2-2)nd base opening portion.

13. The method of claim 12, wherein a width of the (2-2)nd base opening portion is less than a width of the (2-1)st base opening portion.

14. The method of claim 12, wherein the disposing of the metal layer includes disposing the metal layer in the (2-1)st base opening portion.

15. The method of claim 12, wherein the disposing of the adhesive member includes disposing the adhesive member in the (2-2)nd base opening portion.

16. The method of claim 11, wherein the adhesive member is in contact with each of the base layer, the metal layer, and the second mask layer.

17. The method of claim 11, wherein the adhesive member does not protrude from the second mask layer.

18. The method of claim 11, wherein each of a lateral surface and an upper surface of the metal layer is in contact with the base layer.

19. The method of claim 11, wherein a lower surface of the metal layer is exposed from the base layer.

20. The method of claim 11, wherein the first base opening and the plurality of deposition holes overlap each other.
